(19) United States
(12) Patent Application Publication
(10) Pub. No.: US 2026/0164699 A1
(43) Pub. Date: Jun. 11, 2026

(54) SEMICONDUCTOR DEVICE AND METHOD OF MANUFACTURING THE SEMICONDUCTOR DEVICE

(71) Applicants: Samsung Electronics Co., Ltd., Suwon-si (KR); SEOUL NATIONAL UNIVERSITY R&DB FOUNDATION, Seoul (KR)

(72) Inventors: Huije RYU, Suwon-si (KR); Gwanhyoung LEE, Seoul (KR); Yoona KIM, Seoul (KR); Donghoon MOON, Seoul (KR)

(73) Assignees: Samsung Electronics Co., Ltd., Suwon-si (KR); SEOUL NATIONAL UNIVERSITY R&DB FOUNDATION, Seoul (KR)

(21) Appl. No.: 19/409,245

(22) Filed: Dec. 4, 2025

(30) Foreign Application Priority Data
Dec. 11, 2024 (KR) 10-2024-0184138
Sep. 22, 2025 (KR) 10-2025-0136590

(51) Int. Cl. H10D 30/47; H10D 30/00; H10D 30/01; H10D 62/82

(52) U.S. Cl. CPC H10D 30/481; H10D 30/017; H10D 62/8281; H10D 30/502

(57) ABSTRACT

Provided is a semiconductor device including a plurality of transition metal layers spaced apart from each other on a substrate, a channel layer between the plurality of transition metal layers, and a van der Waals material layer on the plurality of transition metal layers, wherein the van der Waals material layer may be a single layer.

### CROSS-REFERENCE TO RELATED APPLICATION

This application is based on and claims priority under 35 U.S.C. § 119 to Korean Patent Application No. 10-2024-0184138, filed on Dec. 11, 2024 and Korean Patent Application No. 10-2025-0136590, filed on Sep. 22, 2025, in the Korean Intellectual Property Office, the disclosure of which is incorporated by reference herein in its entirety.

### BACKGROUND

### 1. Field

The disclosure relates to a semiconductor device and a method of manufacturing the semiconductor device.

### 2. Description of the Related Art

As semiconductor processes become more refined, the sizes of transistors decrease and the area where the gate electrode and the channel contact each other decreases. This may lead to problems due to the short channel effect. In order to reduce short channel effects and improve gate control, research to replace channel materials with two-dimensional semiconductors is ongoing.

Conventional technologies for manufacturing two-dimensional semiconductors, which involve forming a metal electrode after forming a channel region, have resorted to selecting new metal materials or controlling the metal electrode formation method to lower the contact resistance between the two-dimensional semiconductor and the metal.

However, when changing the type of metal material, these technologies are limited in the type of metals, and may use semimetals with a relatively low density of state (DOS), and when changing the metal deposition condition, there may be limitations in the types of metal that can achieve a relatively low contact resistance. Furthermore, there may be a problem that productivity is reduced as the deposition rate is controlled. Therefore, alternatives are being explored.

### SUMMARY

Provided are a semiconductor device and a method of manufacturing the semiconductor device.

Additional aspects will be set forth in part in the description which follows and, in part, will be apparent from the description, or may be learned by practice of the presented embodiments of the disclosure.

According to an aspect of the disclosure, a semiconductor device includes a plurality of transition metal layers spaced apart from each other on a substrate, a channel layer between the plurality of transition metal layers, and a van der Waals material layer on at least one of the plurality of transition metal layers, wherein the van der Waals material layer may be a single layer.

The van der Waals material layer and the at least one of the plurality of transition metal layers may have a same crystallinity.

The van der Waals material layer and the channel layer may have a same crystallinity.

The van der Waals material layer may include graphene.

The semiconductor device may further include a mask layer on the van der Waals material layer.

The mask layer may include at least one of a metal or a conductive oxide.

The mask layer may include a plurality of graphene layers.

The channel layer may include a two-dimensional semiconductor material.

The two-dimensional semiconductor material may include a transition metal dichalcogenide (TMD).

The TMD may include MoS₂, MoSe₂, MoTe₂, WS₂, or WSe₂.

The transition metal layer may include a transition metal of the channel layer.

According to an aspect of the disclosure, a semiconductor device includes a source electrode and a drain electrode spaced apart from each other on a substrate, and a channel layer between the source electrode and the drain electrode, wherein the channel layer may have a same crystallinity as at least one of the source electrode and the drain electrode.

The channel layer may be laterally bonded to at least one of the source electrode and the drain electrode.

The channel layer may include a two-dimensional semiconductor material.

The channel layer may include a transition metal dichalcogenide (TMD).

The TMD includes a transition metal, and at least one of the source electrode and the drain electrode may include the transition metal of the TMD.

According to another aspect of the disclosure, an electronic device includes a semiconductor device and a controller configured to control the semiconductor device, wherein the semiconductor device includes a plurality of transition metal layers spaced apart from a substrate, a channel layer between the plurality of transition metal layers, and a van der Waals material layer on at least one of the plurality of transition metal layers, wherein the van der Waals material layer may be a single layer.

The van der Waals material layer and the transition metal layers may have a same crystallinity.

The van der Waals material layer and the channel layer may have a same crystallinity.

The van der Waals material layer may include graphene.

According to another aspect of the disclosure, a method of manufacturing a semiconductor device may include forming a transition metal layer on a substrate, forming a single van der Waals material layer on the transition metal layer, forming a plurality of mask layers onto the van der Waals material layer so that the plurality of mask layers are spaced apart from each other and so that one or more regions of the van der Waals material layer are exposed, and forming a channel layer in the one or more region exposed by the plurality of mask layers.

The forming of the channel layer may include supplying a chalcogen source to the region while applying heat to the chalcogen source.

The single van der Waals material layer and the channel layer may have a same crystallinity.

The van der Waals material layer and the transition metal layers may have a same crystallinity.

### BRIEF DESCRIPTION OF THE DRAWINGS

The above and other aspects, features and advantages of certain embodiments of the disclosure will be more apparent from the following description taken in conjunction with the accompanying drawings, in which:

FIG. 1 is a perspective view illustrating a semiconductor device according to at least one embodiment;

FIG. 2 is an enlarged perspective view of a portion A in FIG. 1;

FIG. 3 is an enlarged cross-sectional view of the portion A in FIG. 1;

FIGS. 4A to 4C are diagrams illustrating a method of manufacturing a semiconductor device according to at least one embodiment;

FIG. 5 is a perspective view illustrating a semiconductor device according to at least one embodiment;

FIG. 6 is a perspective view illustrating a semiconductor device according to at least one embodiment;

FIG. 7 is a cross-sectional transmission electron microscope image of a semiconductor device according to at least one embodiment;

FIG. 8 is an optical image of a semiconductor device according to at least one embodiment;

FIG. 9 is a graph of voltage and current transfer characteristics of a semiconductor device according to at least one embodiment;

FIG. 10 is a schematic block diagram of a display driver IC (DDI) including a field effect transistor and a display device including the DDI according to at least one embodiment;

FIG. 11 is a block diagram of an electronic system including a semiconductor device according to at least one embodiment; and

FIG. 12 is a block diagram of an electronic system including a semiconductor device according to at least one embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, a semiconductor device and a method of manufacturing the semiconductor device according to various embodiments will be described in detail with reference to the accompanying drawings. In the following drawings, the same reference numerals refer to the same components and the size of each component in the drawings may be exaggerated for clarity and convenience of description. In addition, the embodiments described below are merely exemplary and various modifications are possible from these embodiments. Additionally, when the terms “about” or “substantially” are used in this specification in connection with a numerical value and/or geometric term, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry.

Hereinafter, the term “upper portion” or “on” may also include “to be present above on a non-contact basis” as well as “to be on the top portion in directly contact with”. Additionally, spatially relative terms, such as above, below, etc. are represented herein based on the direction illustrated in the drawings and may be represented otherwise when the orientation of the corresponding object changes. In other words, such spatially relative terms are intended to encompass different orientations of the device in use or operation in addition to the orientation depicted in the figures, such that the device may be otherwise oriented (rotated 90 degrees or at other orientations) and the spatially relative terms used herein interpreted accordingly. The singular expression includes plural expressions unless the context clearly implies otherwise. In addition, when a part “includes” a component, this means that the part may further include other components, not excluding other components unless otherwise stated.

The use of the term “the” and similar indicative terms may correspond to both singular and plural. If there is no explicit description or contrary description of the order of the steps or operations constituting the method, these steps or operations may be carried out in an appropriate order and are not necessarily limited to the described order.

The connection or connection members of lines between the components shown in the drawings exemplarily represent functional connection and/or physical or circuit connections and may be replaceable or represented as various additional functional connections, physical connections, or circuit connections in an actual device. Also, the terms such as “unit” and “module” described in the specification mean units that are configured to process at least one function or operation, and may be implemented as processing circuitry such as hardware, software, or a combination of hardware and software. For example, the processing circuitry may include, but is not limited to, a central processing unit (CPU), an application processor (AP), an arithmetic logic unit (ALU), a graphic processing unit (GPU), a digital signal processor, a microcomputer, a field programmable gate array (FPGA), a System-on-Chip (SoC) a programmable logic unit, a microprocessor, or an application-specific integrated circuit (ASIC), etc., unless expressly indicated otherwise.

The use of all examples or exemplary terms is merely for describing a technical idea in detail and the scope is not limited to the examples or exemplary terms unless limited by the claims.

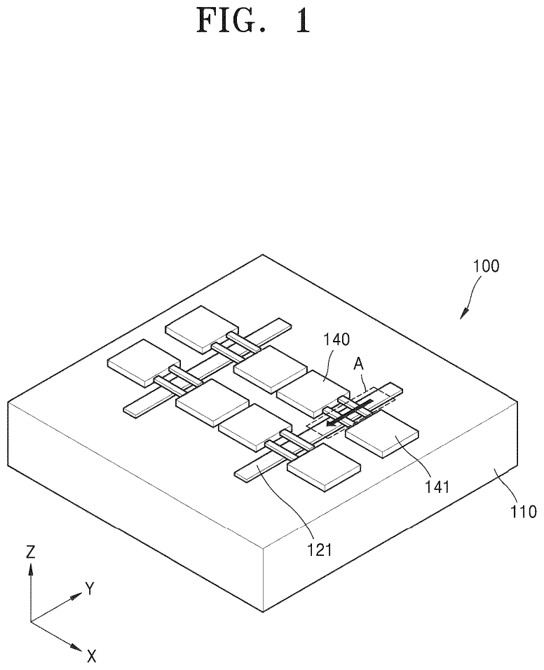

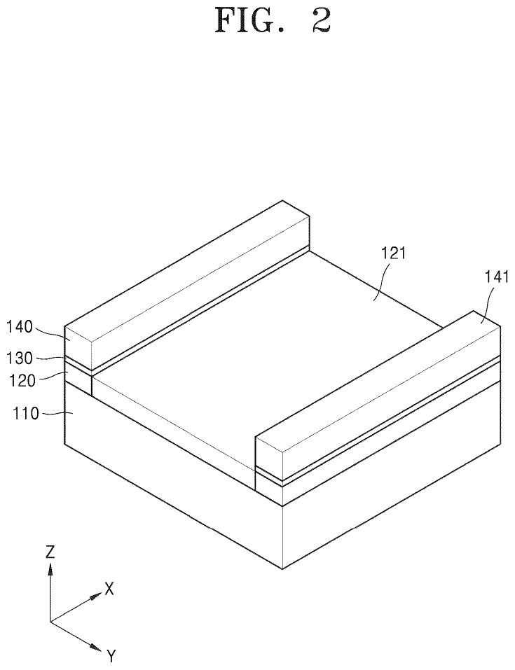

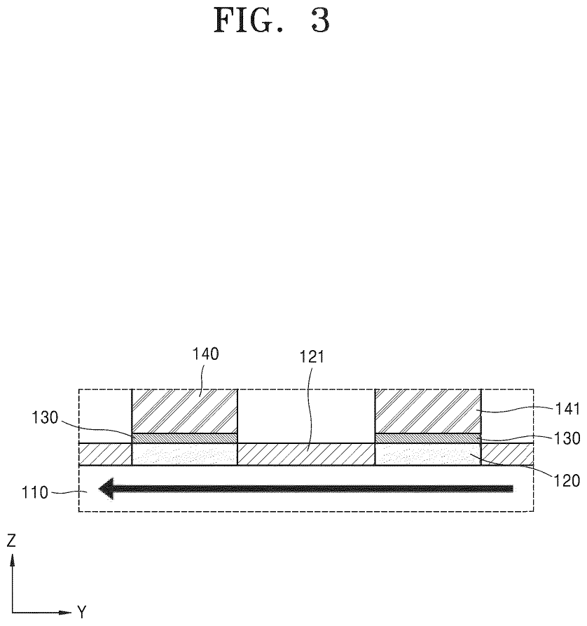

FIG. 1 is a perspective view illustrating a semiconductor device according to at least one embodiment. FIG. 2 is an enlarged perspective view of a portion A in FIG. 1, and FIG. 3 is an enlarged cross-sectional view of the portion A in FIG. 1.

Referring to FIGS. 1, 2, and 3, a semiconductor device 100 may include a first mask layer 140 and a second mask layer 141 spaced apart from each other on a substrate 110 and a channel layer 121 between the first mask layer 140 and the second mask layer 141. Although FIG. 1 illustrates that the semiconductor device 100 includes four first mask layers 140, four second mask layers 141, and two channel layers 121, this is only an example; and the semiconductor device 100 may include a plurality of first mask layers 140, a plurality of second mask layers 141, and a plurality of channel layers 121.

The semiconductor device 100 may include a plurality of transition metal layers 120 spaced apart from each other on the substrate 110, a channel layer 121 between the plurality of transition metal layers 120, and a van der Waals material layer 130 arranged on each of the plurality of transition metal layers 120.

The substrate 110 may be an insulating substrate or a semiconductor substrate having an insulating layer formed on a surface thereof. The substrate 110 include, for example, at least one of a group IV semiconductor (such as germanium (Ge), silicon (Si), (e.g., single crystal silicon, polycrystalline silicon, and/or amorphous silicon), and/or the like), a group IV-IV compound semiconductor (such as silicon germanium (SiGe), silicon carbide (SiC), and/or the like), and/or a group III-V compound semiconductor (such as gallium arsenide (GaAs), indium arsenide (InAs), indium phosphide (InP), and/or the like), and/or the like. According to at least one example, the substrate 110 may be based on a silicon-bulk substrate or a silicon-on-insulator (SOI) substrate. The substrate 110 is not limited to a bulk or SOI substrate, but may be a substrate based on an epitaxial wafer, a polished wafer, an annealed wafer, and/or the like. The substrate 110 may include a conductive region, for example, an impurity-doped well, or various impurity-doped structures. In addition, the substrate 110 may constitute a p-type substrate or an n-type substrate according to the type of impurity ion to be doped. Additionally, in at least one embodiment, the substrate 110 may include a gate electrode (not illustrated) deposed under the channel layer 121. A gate insulating layer may be further provided to electrically insulate the channel layer 121 from the gate electrode. In such cases, the semiconductor device 100 may be referred to as a bottom-gate structure. However, the example embodiments are not limited thereto; for example, a gate electrode and gate insulating layer may be provided onto the channel layer 121.

The transition metal layer 120 includes a transition metal of the channel layer 121. The transition metal layer 120 may include, for example, at least one of Mo, Nb, V, Ta, Ti, Zr, Hf, Tc, Re, or W. The composition of the transition metal layer 120 may selected to form a metal-semiconductor junction structure together with the channel layer 121.

The channel layer 121 may be formed through a chalcogenization process of the transition metal layer 120. The channel layer 121 may be laterally bonded to the plurality of transition metal layers 120 between the plurality of transition metal layers 120.

The channel layer 121 may include a two-dimensional semiconductor material. The channel layer 121 may include a transition metal dichalcogenide (TMD). TMD may be represented by, for example, MX₂, where M represents a transition metal and X represents a chalcogen element. For example, M may be at least one of molybdenum (Mo), tungsten (W), niobium (Nb), vanadium (V), tantalum (Ta), titanium (Ti), zirconium (Zr), hafnium (Hf), technetium (Tc), rhenium (Re_, and/or the like, and X may be at least one of sulfur(S), selenium (Se), tellurium (Te), and/or the like. Therefore, for example, the TMD may include MoS₂, WSe₂, MoSe₂, or WS₂. According to at least one example, the transition metal M of the channel layer 121 may be (or include) the same transition metal of the transition metal layer 120.

The van der Waals material layer 130 includes a van der Waals material, for example, a van der Waals material having two-dimensional (2D) crystalline structure. The van der Waals material layer 130 may be a single layer. The van der Waals material layer 130 may be (or include), for example, a single layer of graphene. In such cases, the crystal structure of the van der Waals material may include, e.g., a hexagonal lattice structure extending in parallel with the surface on which the van der Waals material layer 130 is provided. The van der Waals material layer 130 may be provided between the transition metal layer 120 and the first mask layer 140 and/or may be provided between the transition metal layer 120 and the second mask layer 141.

The transition metal layer 120 may have a same crystallinity as the van der Waals material layer 130. The transition metal layer 120 may have the same crystallinity as that of the van der Waals material layer 130 by performing heat treatment according to the hypotaxy process. For example, when a graphene single layer is used as the van der Waals material layer 130, the transition metal layer 120 may be formed to have the same (or substantially similar) crystallinity as graphene. The same crystallinity may mean that at least one of a crystal direction, a crystal structure, and a lattice constant is the same. For example, the transition metal layer 120 may have a hexagonal plate shape crystal structure substantially the same as graphene. In other words, in at least some examples, the transition metal layer 120 may have a three-dimensional (3D) crystal structure wherein at least one of a crystal direction, a crystal structure, and a lattice constant is the same (or substantially similar to) the 2D crystalline structure of the van der Waals material. For example, at least one of a crystal direction, a crystal structure, and a lattice constant of the transition metal layer 120 and the van der Waals material layer 130 may be the same at an interface between the transition metal layer 120 and the van der Waals material layer 130.

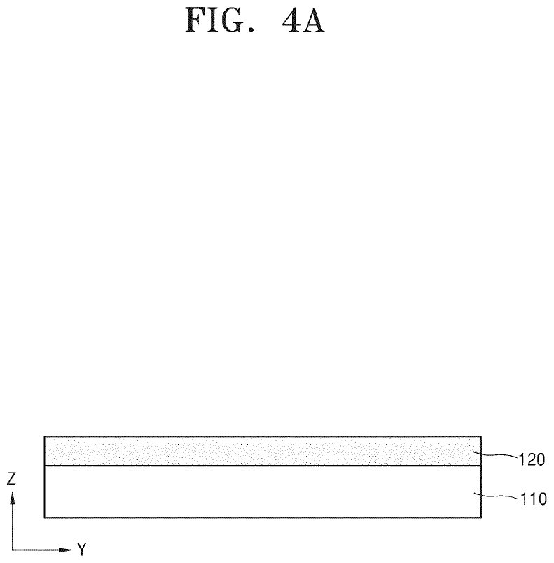

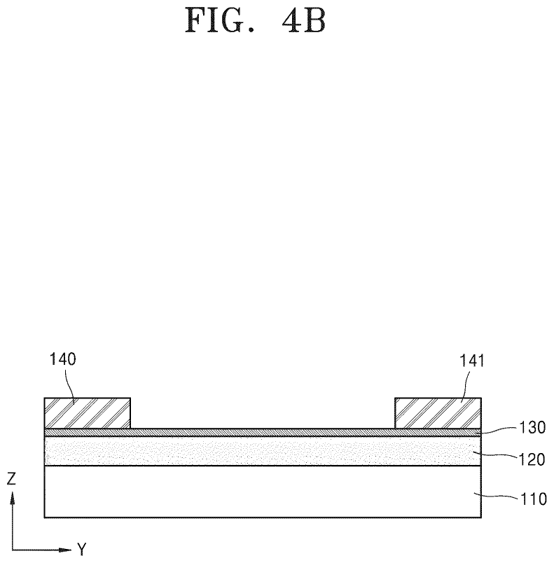

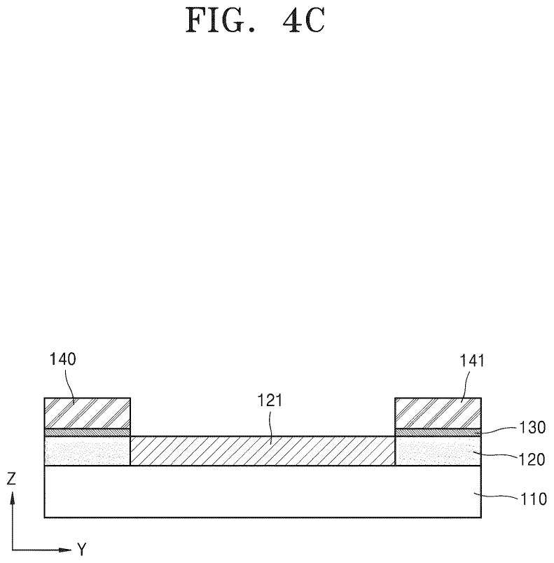

In the channel layer 121, a grain direction and a grain size may be determined according to the crystallinity of the van der Waals material layer 130. The channel layer 121 may have a same (or substantially similar) crystallinity as the van der Waals material layer 130. The same crystallinity may mean that at least one of a crystal direction, a crystal structure, and a lattice constant is the same. A method of allowing the channel layer 121 to have the same crystallinity as the van der Waals material layer 130 will be described later with reference to FIGS. 4A to 4C.

A first mask layer 140 and a second mask layer 141 may be provided on the van der Waals material layer 130. The first mask layer 140 and the second mask layer 141 may each include an electrically conductive material, such a metal and/or a conductive oxide. The metal may include, for example, at least one of Au, Ti, TiN, TaN, W, Mo, WN, Pt, Ni, and/or the like. The conductive oxide may include, for example, indium tin oxide (ITO), indium zinc oxide (IZO), and/or the like. In at least some examples, the first mask layer 140 and/or the second mask layer 141 may include a graphene layer and/or a plurality of graphene layers.

The first mask layer 140 and the second mask layer 141 may be spaced apart from each other with the channel layer 121 therebetween. The channel layer 121 may extend in the first direction (Y-direction), and the first mask layer 140 and the second mask layer 141 may be spaced apart from each other in a second direction (X-direction) perpendicular to the first direction (Y-direction) with the channel layer 121 therebetween. Additionally, the first mask layer 140 and the second mask layer 141 may each include a first portion and a second portion, wherein the first portions and the channel layer 121 are spaced apart from each other in the second direction (X-direction) and wherein the second portions are each electrically connected to the channel layer 121 therebetween. In at least one example, the second portion of the first mask layer 140 may extend towards and be spaced apart from the first portion of the second mask layer 141 and the second portion of the second mask layer 141 may extend towards and be spaced apart from the first portion of the first mask layer 140. However, the examples are not limited thereto.

The first mask layer 140 may be a source electrode and the second mask layer 141 may be a drain electrode. However, the example embodiments are not limited thereto, and the first mask layer 140 may be a drain electrode and the second mask layer 141 may be a source electrode. When the first mask layer 140 and the second mask layer 141 are a source electrode and a drain electrode, respectively, the channel layer 121 may be a passage through which a current flows between the first mask layer 140 and the second mask layer 141.

The semiconductor device 100 includes, for example, a source electrode 140 and a drain electrode 141 spaced apart from each other on a substrate 110, and a channel layer 121 between the source electrode 140 and the drain electrode 141, wherein at least one of the source electrode 140 and the drain electrode 141 may have the same crystallinity as the channel layer 121. The source electrode 140, the drain electrode 141, and the channel layer 121 may be formed to have the same crystallinity as, for example, graphene. The source electrode 140, the drain electrode 141, and the channel layer 121 may have, for example, a hexagonal plate shape crystal structure substantially the same as graphene. The same crystallinity may mean that at least one of a crystal direction, a crystal structure, and a lattice constant is the same. Meanwhile, at least one of the source electrode 140 and the drain electrode 141 may include a transition metal of the channel layer 121.

The semiconductor device 100 according to at least one embodiment may include a channel layer having a relatively high crystallinity, and may ensure a lower contact resistance with higher charge transfer efficiency.

FIGS. 4A to 4C are diagrams illustrating a method of manufacturing a semiconductor device according to at least one embodiment. A method of manufacturing a semiconductor device according to at least one embodiment illustrates a method of manufacturing the semiconductor device 100 of FIG. 1. In describing FIGS. 4A to 4C, redundant descriptions to those of FIGS. 1 to 3 may be omitted.

Referring to FIG. 4A, the transition metal layer 120 may be formed on the substrate 110. The transition metal layer 120 may be formed in the form of a thin film. For example, in at least some embodiments, the forming the transition metal layer 120 may include deposited or transferred a transition metal onto the substrate 110. Then, a van der Waals material layer 130 may be formed on the transition metal layer 120. For example, in at least some embodiments, the forming the van der Waals material layer 130 may include deposited or transferred a van der Waals material onto the transition metal layer 120.

Referring to FIG. 4B, after the van der Waals material layer 130 is formed on the transition metal layer 120, the first mask layer 140 and the second mask layer 141 may be formed on the van der Waals material layer 130 such that the first mask layer 140 and the second mask layer 141 are spaced apart from each other. The van der Waals material layer 130 may be a single layer. The first mask layer 140 and the second mask layer 141 may be provided on both side regions of the van der Waals material layer 130.

Referring to FIG. 4C, the channel layer 121 may be formed in a region of the substrate 110 where the first mask layer 140 and the second mask layer 141 are not formed. The channel layer 121 may be formed through a method of supplying a chalcogen source to the transition metal layer 120 and the van der Waals material layer 130 while applying heat to the transition metal layer 120 and the van der Waals material layer 130. In this process, the van der Waals material layer 130 may be removed from the region of the substrate 110 where the first mask layer 140 and the second mask layer 141 are not formed.

In the channel layer 121 formed by chalcogenization after forming the van der Waals material layer 130 on the transition metal layer 120, the grain direction and grain size may be determined according to the crystallinity of the van der Waals material layer 130. The channel layer 121 may have a same crystallinity as the van der Waals material layer 130. Such a method of forming the channel layer 121 may be referred to as a hypotaxy method.

According to method of manufacturing the semiconductor device according to at least one embodiment, the channel layer 121 having higher quality and higher crystallinity at a relatively low temperatures may be formed by utilizing the hypotaxy method. In addition, when the first mask layer 140 and the second mask layer 141 are a source electrode and a drain electrode, respectively, defects may not occur (or may be comparatively reduced) in the channel layer 121 in contact with the source and drain electrodes because the source and drain electrodes are formed in advance before the channel layer 121 is formed.

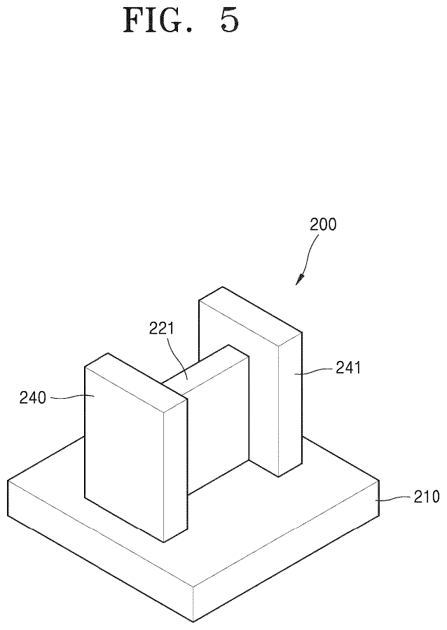

FIG. 5 is a perspective view illustrating a semiconductor device according to at least one embodiment.

Referring to FIG. 5, a semiconductor device 200 may include a first mask layer 240 and a second mask layer 241 spaced apart from each other on a substrate 210, and a channel layer 221 between the first mask layer 240 and the second mask layer 241.

The channel layer 221 may be formed through a chalcogenization process of a transition metal layer (not shown) surrounded by a van der Waals material layer (not shown). The channel layer 221 may be laterally bonded to a plurality of transition metal layers (not shown) between a plurality of transition metal layers (not shown).

A transition metal layer (not shown) surrounded by a van der Waals material layer (not shown) may be provided inside the first mask layer 240. A transition metal layer (not shown) surrounded by a van der Waals material layer (not shown) may be provided inside the second mask layer 241.

The van der Waals material layer (not shown) may be provided between the transition metal layer (not shown) and the first mask layer 240. The van der Waals material layer (not shown) may be provided between the transition metal layer (not shown) and the second mask layer 241.

The substrate 210, the transition metal layer (not shown), the channel layer 221, the van der Waals material layer (not shown), the first mask layer 240, and the second mask layer 241 may be the same as the substrate 110, the transition metal layer 120, the channel layer 121, the van der Waals material layer 130, the first mask layer 140, and the second mask layer 141 described with reference to FIGS. 1 to 3. In describing FIG. 5, redundant descriptions of FIGS. 1 to 3 are omitted.

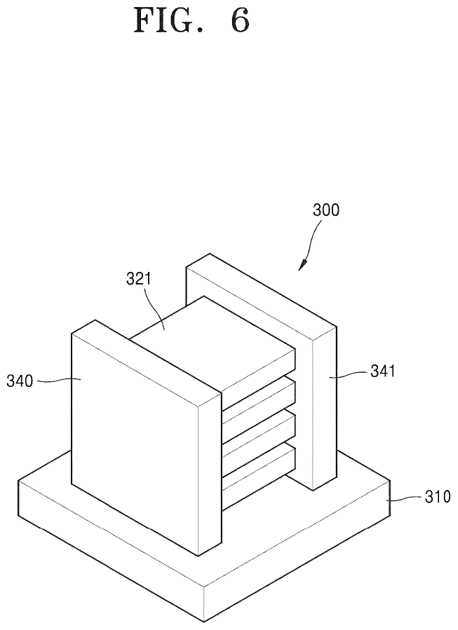

FIG. 6 is a perspective view illustrating a semiconductor device according to at least one example embodiment.

Referring to FIG. 6, a semiconductor device 300 may include a first mask layer 340 and a second mask layer 341 spaced apart from each other on a substrate 310, and a plurality of channel layers 321 between the first mask layer 340 and the second mask layer 341.

The channel layer 321 may be formed through a chalcogenization process of a transition metal layer (not shown) surrounded by a van der Waals material layer (not shown). The channel layer 321 may be laterally bonded to a plurality of transition metal layers (not shown) between a plurality of transition metal layers (not shown).

A plurality of transition metal layers (not shown) surrounded by a van der Waals material layer (not shown) may be provided inside the first mask layer 340. A plurality of transition metal layers (not shown) surrounded by a van der Waals material layer (not shown) may be provided inside the second mask layer 341.

The van der Waals material layer (not shown) may be provided between the transition metal layer (not shown) and the first mask layer 340. The van der Waals material layer (not shown) may be provided between the transition metal layer (not shown) and the second mask layer 341.

The substrate 310, the transition metal layer (not shown), the channel layer 321, the van der Waals material layer (not shown), the first mask layer 340, and the second mask layer 341 may be the same as the substrate 110, the transition metal layer 120, the channel layer 121, the van der Waals material layer 130, the first mask layer 140, and the second mask layer 141 described with reference to FIGS. 1 to 3. In describing FIG. 6, redundant descriptions of FIGS. 1 to 3 are omitted.

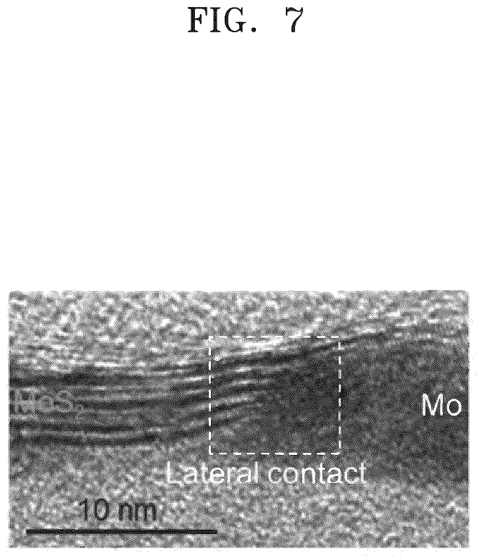

FIG. 7 is a cross-sectional transmission electron microscope image of a semiconductor device according to at least one embodiment.

Referring to FIG. 7, a coupling relationship between a transition metal layer including Mo and a channel layer including MoS₂ may be identified. The transition metal layer including Mo and the channel layer including MoS₂ may be laterally bonded through lateral contact. As the transition metal layer and the channel layer are laterally bonded to each other, contact resistance may be reduced due to a higher charge transfer efficiency, and performance of the semiconductor device may be improved.

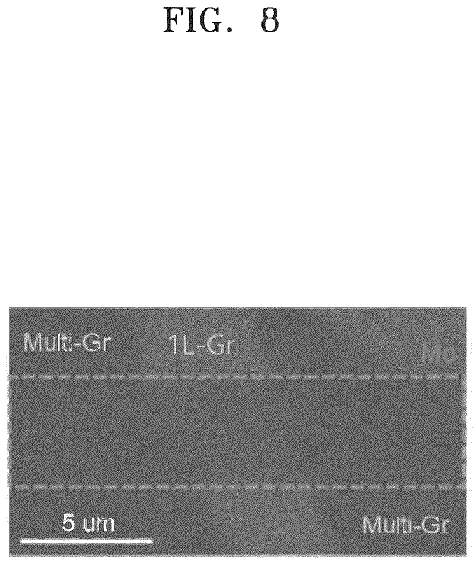

FIG. 8 is an optical image of a semiconductor device according to at least one embodiment.

Referring to FIG. 8, a semiconductor device includes a transition metal layer including Mo, a van der Waals material layer including a single graphene layer, a first mask layer including a plurality of graphene layers, and a second mask layer including a plurality of graphene layers.

When a van der Waals material layer including a single graphene layer is provided on the transition metal layer including Mo, a plurality of graphene layers are provided on the van der Waals material layer, and the hypotaxy process is carried out, it may be seen that the transition metal layer in the region without the plurality of graphene layers is changed to MoS₂.

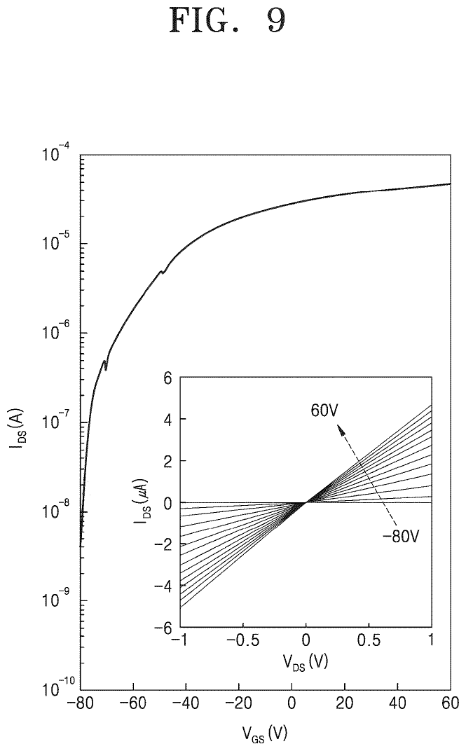

FIG. 9 is a graph of voltage and current transfer characteristics of a semiconductor device according to at least one embodiment.

Referring to FIG. 9, a gate electrode voltage (V_{GS})-drain current (I_{DS}) transfer characteristic graph and a drain electrode voltage (V_{DS})-drain current (I_{DS}) transfer characteristic graph of a semiconductor device according to at least one embodiment may be confirmed.

Through the gate electrode voltage (V_{GS})-drain current (I_{DS}) transfer characteristic graph and the drain electrode voltage (V_{DS})-drain current (I_{DS}) transfer characteristic graph of a semiconductor device, it may be confirmed that the transition metal layer is chalcogenized into the channel layer, so that the semiconductor device exhibits semiconductor characteristics in which current is controlled according to the voltage of the gate electrode, and that the van der Waals material layer is etched during the chalcogenization process to prevent (or reduce) leakage current.

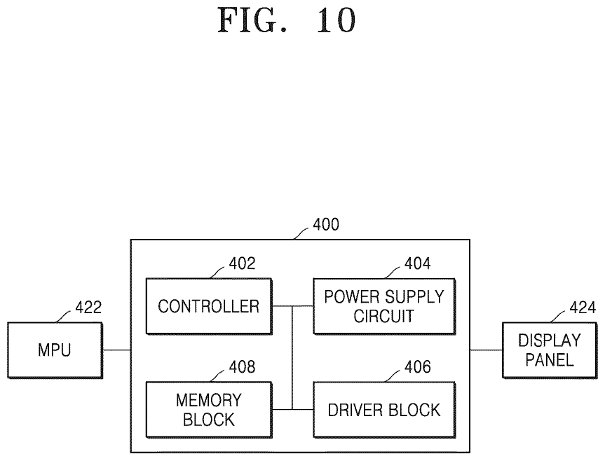

FIG. 10 is a schematic block diagram of a display driver IC (DDI) and a display device including the DDI according to at least one embodiment.

Referring to FIG. 10, the DDI 400 may include a controller 402, a power supply circuit 404, a driver block 406, and a memory block 408. The controller 402 receives and decodes a command applied from the main processing unit (MPU) 422, and controls each block of the DDI 400 to implement an operation according to the command. The power supply circuit 404 generates a driving voltage in response to the control of the controller 402. The driver block 406 drives the display panel 424 using the driving voltage generated by the power supply circuit 404 in response to the control of the controller 402. The display panel 424 may include a liquid crystal display panel or a plasma display panel. The memory block 408 is a block that temporarily stores commands input to the controller 402 or control signals output from the controller 402, or stores necessary data, and may include a memory such as random access memory (RAM) and read only memory (ROM). The power supply circuit 404 and the driver block 406 may include the one or more of the semiconductor devices 100, 200, and 300 according to the example embodiments described above with reference to FIGS. 1 to 6.

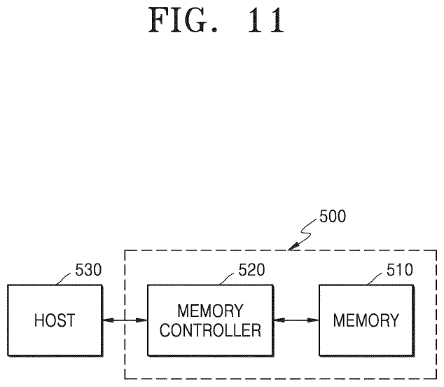

FIG. 11 is a block diagram of an electronic system including a semiconductor device according to at least one embodiment.

Referring to FIG. 11, an electronic system 500 includes a memory 510 and a memory controller 520. The memory controller 520 may control the memory 510 to read data from the memory 510 and/or write data to the memory 510 in response to a request from a host 530. At least one of the memory 510 and the memory controller 520 may include one or more of the semiconductor devices 100, 200, and 300 according to the example embodiments described above with reference to FIGS. 1 to 6.

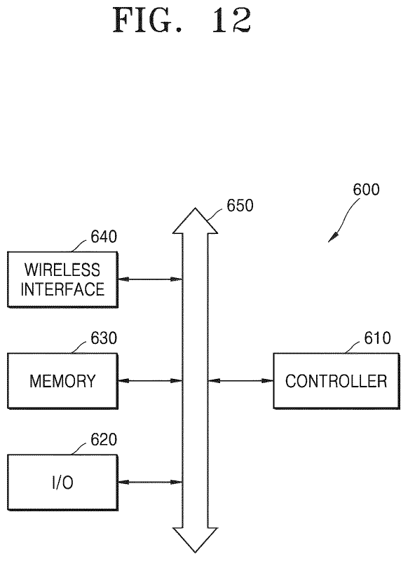

FIG. 12 is a block diagram of an electronic system including a semiconductor device according to another embodiment.

Referring to FIG. 12, the electronic system 600 may configure a wireless communication device, or a device capable of transmitting and/or receiving information under a wireless environment. The electronic system 600 includes a controller 610, an input/output device (I/O) 620, a memory 630, and a wireless interface 640, each of which is interconnected through a bus 650.

The controller 610 may include at least one of a microprocessor, a digital signal processor, or a processing device similar thereto. The input/output device 620 may include at least one of a keypad, a keyboard, and a display. The memory 630 may be used to store instructions or commands executed by the controller 610. For example, the memory 630 may be used to store user data. The electronic system 600 may use the wireless interface 640 to transmit/receive data through a wireless communication network. The wireless interface 640 may include an antenna and/or a wireless transceiver. In some embodiments, the electronic system 600 may be used in communication interface protocols of third-generation communication systems, such as code division multiple access (CDMA), global system for mobile communications (GSM), north American digital cellular (NADC), extended-time division multiple access (E-TDMA), and/or wide band code division multiple access (WCDMA). The electronic system 600 may include one or more of the semiconductor devices 100, 200, and 300 according to the example embodiments described above with reference to FIGS. 1 to 6.

According to the semiconductor device and the semiconductor device manufacturing method of the present disclosure, a channel layer with a relatively high crystallinity may be included and lower contact resistance with higher charge transfer efficiency may be secured. According to the present disclosure, a semiconductor device including a channel layer having a relatively high crystallinity is provided.

According to the present disclosure, a method of manufacturing a semiconductor device capable of ensuring lower contact resistance with higher charge transfer efficiency is provided.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A semiconductor device comprising:
a plurality of transition metal layers spaced apart from each other on a substrate;
a channel layer between the plurality of transition metal layers; and
a van der Waals material layer on at least one of the plurality of transition metal layers, wherein the van der Waals material layer is a single layer.

2. The semiconductor device of claim 1, wherein the van der Waals material layer and the at least one of the plurality of transition metal layers have a same crystallinity.

3. The semiconductor device of claim 1, wherein the van der Waals material layer and the channel layer have a same crystallinity.

4. The semiconductor device of claim 1, wherein the van der Waals material layer comprises graphene.

5. The semiconductor device of claim 1, further comprising:
a mask layer on the van der Waals material layer.

6. The semiconductor device of claim 5, wherein the mask layer comprises at least one of a metal or a conductive oxide.

7. The semiconductor device of claim 5, wherein the mask layer comprises a plurality of graphene layers.

8. The semiconductor device of claim 1, wherein the channel layer comprises a two-dimensional semiconductor material.

9. The semiconductor device of claim 8, wherein the two-dimensional semiconductor material comprises a transition metal dichalcogenide (TMD).

10. The semiconductor device of claim 9, wherein the TMD comprises at least one of MoS₂, MoSe₂, MoTe₂, WS₂, or WSe₂.

11. The semiconductor device of claim 1, wherein the plurality of transition metal layers includes a transition metal, and the channel layer includes the transition metal.

12. A semiconductor device comprising:
a source electrode and a drain electrode spaced apart from each other on a substrate; and
a channel layer between the source electrode and the drain electrode, the channel layer having a same crystallinity as at least one of the source and drain electrodes.

13. The semiconductor device of claim 12, wherein the channel layer is laterally bonded to at least one of the source electrode or the drain electrode.

14. The semiconductor device of claim 12, wherein the channel layer comprises a two-dimensional semiconductor material.

15. The semiconductor device of claim 12, wherein the channel layer comprises a transition metal dichalcogenide (TMD).

16. The semiconductor device of claim 15, wherein the TMD includes a transition metal, and at least one of the source electrode or the drain electrode includes the transition metal.

17. A method of manufacturing a semiconductor device, the method comprising:
forming a transition metal layer on a substrate;
forming a single van der Waals material layer on the transition metal layer;
forming a plurality of mask layers onto the van der Waals material layer so that the plurality of mask layers are spaced apart from each other and so that one or more regions of the van der Waals material layer are exposed; and
forming a channel layer in the one or more region exposed by the plurality of mask layers.

18. The method of claim 17, wherein the forming of the channel layer comprises supplying a chalcogen source to the one or more regions while applying heat to the chalcogen source.

19. The method of claim 17, wherein the single van der Waals material layer and the channel layer have a same crystallinity.

20. The method of claim 17, wherein the single van der Waals material layer comprises graphene.
